(19) United States
(12) Patent Application Publication
(10) Pub. No.: US 2025/0101568 A1
(43) Pub. Date: Mar. 27, 2025

(54) DEPOSITION MASK AND METHOD OF FABRICATING THE SAME

(71) Applicant: Samsung Display Co., LTD., Yongin-si (KR)

(72) Inventors: Jae Been LEE, Yongin-si (KR); Mi Yeon CHO, Yongin-si (KR); Dae Ho SONG, Yongin-si (KR); Ju Won YOON, Yongin-si (KR); Yea Hwane CHOI, Yongin-si (KR)

(21) Appl. No.: 18/739,193

(22) Filed: Jun. 10, 2024

(30) Foreign Application Priority Data
Sep. 27, 2023 (KR) 10-2023-0131143

(51) Int. Cl. C23C 14/04; G03F 7/00; H10K 59/12

(52) U.S. Cl. CPC C23C 14/042; G03F 7/0035; H10K 59/12

(57) ABSTRACT

A method of fabricating a deposition mask includes: preparing a silicon on insulator (SOI) substrate including an upper silicon substrate, a lower silicon substrate, and an insulating layer between the upper silicon substrate and the lower silicon substrate; forming a mask membrane having a plurality of openings by patterning the upper silicon substrate; forming a first protective layer on the upper silicon substrate and a second protective layer on the lower silicon substrate; forming a cell opening by patterning the lower silicon substrate; and removing the first protective layer and the second protective layer.

### CROSS-REFERENCE TO RELATED APPLICATION

The present application claims priority to and the benefit of Korean Patent Application No. 10-2023-0131143, filed on Sep. 27, 2023, in the Korean Intellectual Property Office, the entire disclosure of which is incorporated herein by reference.

### BACKGROUND

### 1. Field

Aspects of embodiments of the present disclosure relate to a deposition mask and a method of fabricating the same.

### 2. Description of the Related Art

A wearable device in the form of glasses or a helmet and which focuses an image at a location close to the user's eyes is being developed. For example, a wearable device may be a head mounted display (HMD) device or an augmented reality (AR) glasses. Such a wearable device provides a user with an augmented reality (hereinafter referred to as “AR”) screen (or image) or a virtual reality (hereinafter referred to as “VR”) screen (or image).

To allow users to use a wearable device, such as a HMD device and AR glasses, for a long time without dizziness, the wearable device should exhibit display specifications of at least about 2,000 PPI (pixels per inch). To satisfy this criteria, organic light-emitting diode on silicon (OLEDoS) technology is emerging, which is high-resolution small organic light-emitting element display device. OLEDOS is a technology for disposing organic light-emitting diodes (OLEDs) on a semiconductor wafer substrate on which a complementary metal oxide semiconductor (CMOS) is disposed.

To manufacture a display device exhibiting a high resolution of about 2000 PPI or higher, a high resolution deposition mask is required. Silicon masks that can form masks with the precision of semiconductor processes are being researched and developed. A silicon mask is a mask that deposits an inorganic film pattern on a silicon substrate and allows the inorganic film pattern to act as a mask membrane. However, silicone masks are vulnerable to stress due to the thin mask membrane.

### SUMMARY

Embodiments of the present disclosure provide a deposition mask that is thin yet highly resistant to stress by forming a mask membrane using some of the silicon layer included in a SOI (Silicon on Insulator) substrate and a method of fabricating the same.

According to an embodiment of the present disclosure, a method of fabricating a deposition mask includes: preparing a silicon on insulator (SOI) substrate including an upper silicon substrate, a lower silicon substrate, and an insulating layer between the upper silicon substrate and the lower silicon substrate; forming a mask membrane having a plurality of openings by patterning the upper silicon substrate; forming a first protective layer on the upper silicon substrate and a second protective layer on the lower silicon substrate; forming a cell opening by patterning the lower silicon substrate; and removing the first protective layer and the second protective layer.

The insulating layer may include silicon oxide (SiOₓ).

The patterning of the upper silicon substrate may include forming a first photoresist pattern on the upper silicon substrate, forming the plurality of openings by using the first photoresist pattern, and removing the first photoresist pattern.

The forming of the first protective layer and the second protective layer may include performing thermal oxidation process with respect to the upper silicon substrate and the lower silicon substrate, respectively.

The forming of the cell opening may include KOH wet etching process by adjusting an etch ratio in respect to silicon oxide (SiOₓ) in the second protective layer and silicon (Si) in the lower silicon substrate.

The removing of the first protective layer and the second protective layer may include a strip process using HF or buffered oxide etchant (BOE).

The SOI substrate may include a plurality of cell areas and a mask rib region extending around the plurality of cell areas, and the method may further include forming a spacer by etching the upper silicon substrate in the mask rib region.

The spacer may have a height facing a substrate to be subjected to deposition.

The method may further include depositing a dummy inorganic film covering the mask membrane after removing the first protective layer and the second protective layer.

The dummy inorganic film may include silicon nitride (SiNₓ). The depositing of the dummy inorganic film may include adjusting a deposition thickness on a side of a mask shadow of the mask membrane so that a cross-section of a mask opening in the mask membrane has a regular taper shape.

The forming of the mask membrane may include forming a cross-section of the mask membrane into an inverse taper shape.

The inverse taper shape of the cross-section of the mask membrane may have a shape having a thickness increasing from a bottom surface in an upward direction.

According to an embodiment of the present disclosure, a deposition mask includes: a silicon on insulator (SOI) substrate including an upper silicon substrate, a lower silicon substrate, and an insulating layer between the upper silicon substrate and the lower silicon substrate; a mask membrane formed by etching the upper silicon substrate in each cell area of the SOI substrate, and a cell opening exposing the mask membrane from a rear direction in each of the cell areas.

The insulating layer may include silicon oxide (SiOₓ). The SOI substrate may include a plurality of cell areas and a mask rib region extending around the plurality of cell areas, and the deposition mask may further include a spacer formed by etching the upper silicon substrate in the mask rib region. The spacer may have a height facing a substrate to be subjected to deposition.

The deposition mask may further include a dummy inorganic film covering the mask membrane.

The dummy inorganic film may include silicon nitride (SiNₓ).

A cross-section of the mask membrane may have an inverse taper shape, and the inverse taper shape may be a shape having a thickness increasing from a bottom surface in an upward direction.

According to embodiments of the present disclosure, a thin yet highly stress resistant deposition mask is formed by using a mask membrane using some of the silicon layer included in a SOI (Silicon on Insulator) substrate.

However, aspects and features of the present disclosure are not limited to those set forth herein. The above and other aspects and features of the present disclosure will become more apparent to one of ordinary skill in the art to which the present disclosure pertains by referencing the detailed description of the present disclosure below.

### BRIEF DESCRIPTION OF THE DRAWINGS

The above and other aspects and features of the present disclosure will become more apparent by describing, in detail, embodiments thereof with reference to the attached drawings, in which:

FIG. 1 is a perspective view of a head-mounted display device according to an embodiment of the present disclosure;

FIG. 2 is an exploded perspective view of the head-mounted display device shown in FIG. 1;

FIG. 3 is a perspective view of a head-mounted display device according to an embodiment of the present disclosure;

FIG. 4 is an exploded, perspective view of a display device according to an embodiment of the present disclosure;

FIG. 5 is a cross-sectional view of a portion of a display panel according to an embodiment of the present disclosure;

FIG. 6 is a perspective view of a mask according to an embodiment;

FIG. 7 is a schematic plan view of a mask according to an embodiment of the present disclosure;

FIG. 8 is a flowchart describing steps of a method of fabricating a mask according to an embodiment of the present disclosure;

FIGS. 9 to 13 are cross-sectional views illustrating steps of the method of fabricating a mask described in FIG. 8;

FIG. 14 is a cross-sectional view illustrating a step of a method of patterning an upper silicone substrate according to an embodiment of the present disclosure;

FIG. 15 is a schematic cross-sectional view of a deposition mask according to an embodiment including a spacer; and

FIG. 16 is a schematic cross-sectional view of a deposition mask including a dummy inorganic layer according to an embodiment.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete and will filly convey the scope of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Features of each of various embodiments of the present disclosure may be partially or entirely combined with each other and may technically variously interwork with each other, and respective embodiments may be implemented independently of each other or may be implemented together in association with each other.

Hereinafter, embodiments will be described with reference to the accompanying drawings.

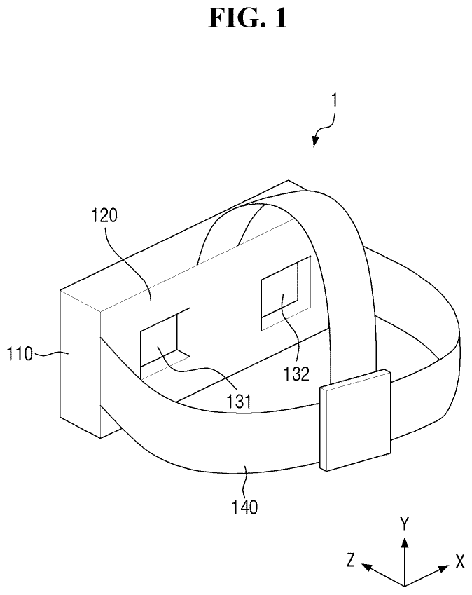

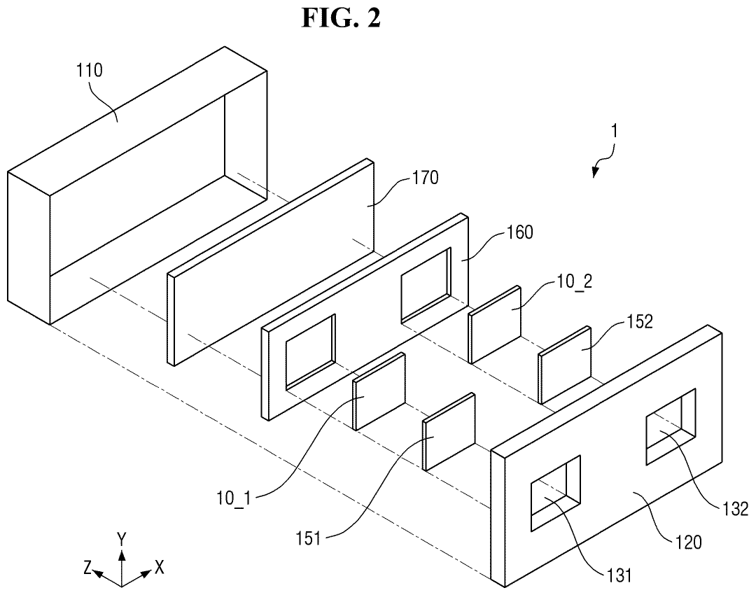

FIG. 1 is a perspective view of a head-mounted display device according to an embodiment of the present disclosure. FIG. 2 is an exploded perspective view of the head-mounted display device shown in FIG. 1.

Referring to FIGS. 1 and 2, a head-mounted display device 1 according to an embodiment includes a first display device 10_1, a second display device 10_2, a display device housing 110, and a housing cover 120, a first eyepiece 131, a second eyepiece 132, a head strap band 140, a middle frame 160, a first optical member 151, a second optical member 152, a control circuit board 170, and a connector.

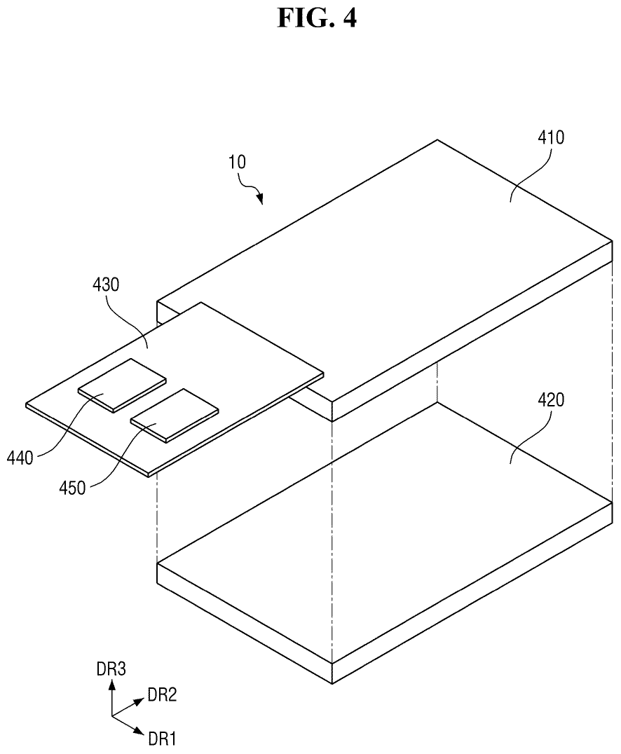

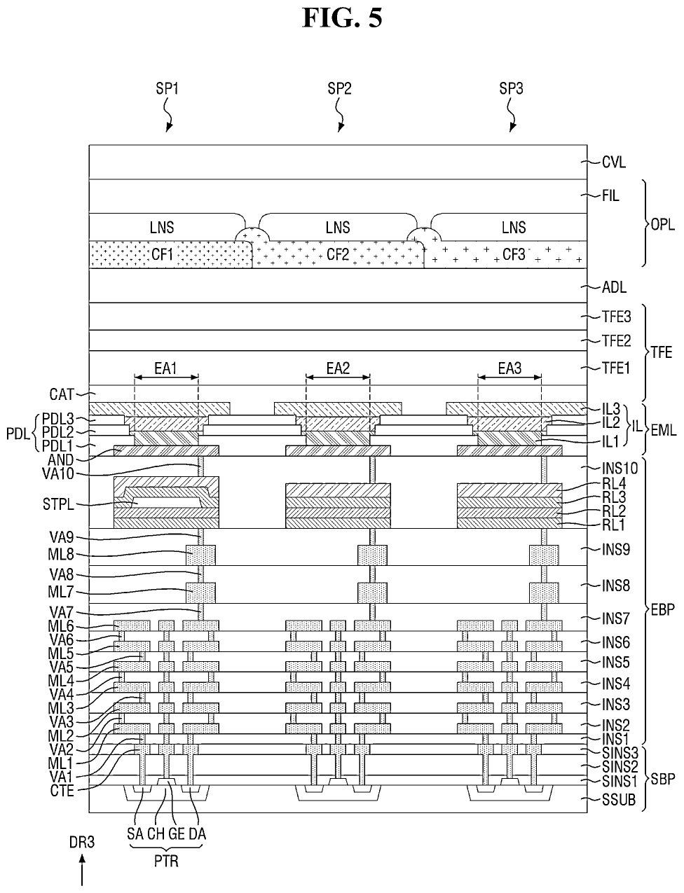

The first display device 10_1 provides images to a user's left eye, and the second display device 10_2 provides images to the user's right eye. Each of the first display device 10_1 and the second display device 10_2 is substantially identical to the display device 10 described with reference to FIGS. 4 and 5. Therefore, descriptions of the first display device 10_1 and the second display device 10_2 will be omitted with the understanding that the description referring to FIGS. 4 and 5 is applicable to the first display device 10_1 and the second display device 10_2.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 supports and fixes the first display device 10_1, the second display device 10_2, and the control circuit board 170.

The control circuit board 170 may be disposed between the middle frame 160 and the display device housing 110. The control circuit board 170 may be connected to the first display device 10_1 and the second display device 10_2 through a connector. The control circuit board 170 may convert an image source input from the outside into digital video data (DATA) and may transmit the digital video data (DATA) to the first display device 10_1 and the second display device 10_2 through the connector.

The control circuit board 170 may transmit digital video data (DATA) associated with a left eye image optimized for the user's left eye to the first display device 10_1 and may transmit digital video data (DATA) associated with a right eye image optimized for the user's right eye to the second display device 10_2. In another embodiment, the control circuit board 170 may transmit the same digital video data (DATA) to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 is disposed to cover the open face (or open side) of the display device housing 110. The housing cover 120 may include the first eyepiece 131 where the user's left eye is placed (or which is aligned with the user's left eye), and the second eyepiece 132 where the user's right eye is placed (or which is aligned with the user's right eye). Although the first eyepiece 131 and the second eyepiece 132 are separately disposed in the embodiment shown in FIGS. 1 and 2, embodiments of the present disclosure are not limited thereto. The first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images of images on the first display device 10_1 magnified by the first optical member 151 through the first eyepiece 131 and may see virtual images of images on the second display device 10_2 magnified by the second optical member 152 through the second eyepiece 132.

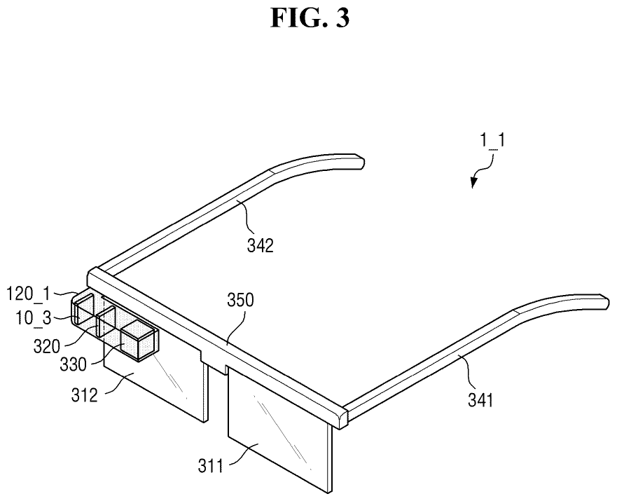

The head strap band 140 fixes the display device housing 110 to the user's head so that the first eyepiece 131 and the second eyepiece 132 of the housing cover 120 remain in line with (e.g., aligned with) the user's left and right eyes, respectively. By implementing a relatively light and small display device housing 110, the head-mounted display device 1 may include (or may be embodied as) an eyeglasses frame, such as is shown in FIG. 3, instead of the head strap band 140 shown in, for example FIG. 1.

In addition, the head-mounted display device 1 may further include a battery for supplying power, an external memory slot for inserting an external memory, and an external connection port and a wireless communication module for receiving an image source. The external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module, but the present disclosure is not limited thereto.

FIG. 3 is a perspective view of a head-mounted display device according to an embodiment of the present disclosure.

Referring to FIG. 3, a head-mounted display device 1_1 according to an embodiment may be a glasses-type display device with a relatively light and small display device housing 120_1. The head-mounted display device 1_1 according to this embodiment may include display devices 10_3, a left-eye lens 311, a right-eye lens 312, a support frame 350, eyeglass temples 341 and 342, optical members 320, optical path conversion members 330, and display device housings 120_1.

The display device 10_3 shown in FIG. 3 is substantially identical to the display device 10 described with reference to FIGS. 4 and 5. Therefore, descriptions of the display device 10_3 will be omitted with the understanding that the description referring to FIGS. 4 and 5 is applicable to the display device 10_3.

The display device housings 120_1 may include the display devices 10_3, the optical members 320, and the optical path conversion members 330. The images displayed on the display device 10_3 may be enlarged by the optical member 320, and the optical paths of the images are converted by the optical path conversion member 330 to be provided to the user's right eye through the right-eye lens 312. As a result, the user can see, with the right eye, augmented reality images that combine virtual images displayed on the display device 10_3 and real world images viewed through the right eye lens 312.

Although the display device housing 120_1 is disposed at the right end of the support frame 350 in the embodiment shown in FIG. 3, embodiments of the present disclosure are not limited thereto. For example, the display device housing 120_1 may be disposed at the left end of the support frame 350. In such an embodiment, images displayed on the display device 10_3 may be provided to the user's left eye. In another embodiment, the display device housing 120_1 may be disposed at both the left and right ends of the support frame 350, respectively. In such an embodiment, the user can view images displayed on the display device 10_3 through both the left and right eyes.

FIG. 4 is an exploded, perspective view of a display device according to an embodiment of the present disclosure.

Referring to FIG. 4, the display device 10 according to an embodiment displays a moving image and/or a still image. The display device 10 according to this embodiment may be employed by portable electronic devices, such as a mobile phone, a smart phone, a tablet PC, a mobile communications terminal, an electronic notebook, an electronic book, a portable multimedia player (PMP), a navigation device, and an ultra-mobile PC (UMPC). For example, the display device 10 may be used as a display unit of a television, a laptop computer, a monitor, an electronic billboard, or an Internet of Things (IOT) device. As other examples, the display device 10 may be applied to a smart watch, a watch phone, or a head-mounted display (HMD) for implementing virtual reality and augmented reality.

According to an embodiment, the display device 10 includes a display panel 410, a heat dissipation layer 420, a circuit board 430, a driver circuit 440, and a power supply circuit 450.

The display panel 410 may have a shape similar to a rectangular shape when viewed from the top. For example, the display panel 410 may have a shape similar to a rectangle having shorter sides in a first direction DR1 and longer sides in a second direction DR2 crossing the first direction DR1 when viewed from the top. In the display panel 410, the corners at where the shorter sides in the first direction DR1 meet the longer sides in the second direction DR2 may be rounded with a curvature (e.g., a predetermined curvature) or may be a right angle. The shape of the display panel 410 when viewed from the top is not limited to a rectangular shape but may be formed in a shape similar to other polygonal shapes, a circular shape, or an elliptical shape. The shape of the display device 10 may follow (or may correspond to) the shape of the display panel 410 when viewed from the top, but embodiments of the present disclosure are not limited thereto.

The display panel 410 has a display area at where images are displayed and a non-display area at where images are not displayed.

The display area includes a plurality of pixels, and each of the plurality of pixels includes a plurality of sub-pixels SP1, SP2, and SP3 (see, e.g., FIG. 5). The sub-pixels SP1, SP2, and SP3 include a plurality of pixel transistors. The pixel transistors are formed via a semiconductor process and may be disposed on a semiconductor substrate SSUB (see, e.g., FIG. 5). For example, the pixel transistors may be implemented as complementary metal oxide semiconductor (CMOS) transistors.

The heat dissipation layer 420 may overlap the display panel 410 in a third direction DR3, which is the thickness direction of the display panel 410. The heat dissipation layer 420 may be disposed on one surface of the display panel 410, for example, on the rear surface of the display panel 410. The heat dissipation layer 420 discharges heat generated in the display panel 410. The heat dissipation layer 420 may include a metal layer, such as graphite, silver (Ag), copper (Cu), and aluminum (Al) having high thermal conductivity.

The circuit board 430 may be electrically connected to a plurality of pads PD in a pad area PDA of the display panel 410 by using a conductive adhesive member, such as an anisotropic conductive film. The circuit board 430 may be a flexible printed circuit board made of a flexible material or may be a flexible film. Although the circuit board 430 is shown in an unfolded state (or configuration) in FIG. 4, the circuit board 430 may be bent. When the circuit board 430 is bent, one end of the circuit board 430 may be disposed on the rear surface of the display panel 410. The one end of the circuit board 430 may be opposite to the opposite end of the circuit board 430, which is connected to the pads PD in the pad area PDA of the display panel 410 by using a conductive adhesive member.

The driver circuit 440 may receive digital video data and timing signals from the outside. The driver circuit 440 may generate a scan timing control signal, an emission timing control signal, and a data timing control signal for controlling the display panel 410 in response to the timing signals.

The power supply circuit 450 may generate a plurality of panel driving voltages in response to a supply voltage from the outside. For example, the power supply circuit 450 may generate a first supply voltage (e.g., voltage VSS), a second supply voltage (e.g., voltage VDD), and a third supply voltage (e.g., voltage VINT) to be applied to the display panel 410.

Each of the driver circuit 440 and the power supply circuit 450 may be implemented as an integrated circuit (IC) and attached to a surface of the circuit board 430.

FIG. 5 is a cross-sectional view showing a portion of a display panel according to an embodiment of the present disclosure. For example, FIG. 5 shows a cross-sectional structure of a portion of a display area that includes a plurality of sub-pixels SP1, SP2, and SP3.

Referring to FIG. 5, the display panel 410 includes a semiconductor backplane SBP, an emission material backplane EBP, an emission material layer EML, an encapsulation layer TFE, an optical layer OPL, a cover layer CVL, and a polarizer.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE that are electrically connected to the pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be formed in the upper surface of the semiconductor substrate SSUB. The well areas WA may be doped with second-type impurities. The second-type impurities may be different from the first-type impurities. For example, when the first-type impurities are p-type impurities, the second-type impurities may be n-type impurities. In another embodiment, when the first-type impurities are n-type impurities, the second-type impurities may be p-type impurities.

Each of the well areas WA has a source region SA associated with a source electrode of a pixel transistor PTR, a drain region DA associated with a drain electrode thereof, and a channel region CH between the source region SA and the drain region DA.

Each of the source region SA and the drain region DA may be doped with the first-type impurities. A gate electrode GE of the pixel transistor PTR may overlap the well area WA in the third direction DR3. The channel region CH may overlap the gate electrode GE in the third direction DR3. The source region SA may be located on one side of the gate electrode GE, and the drain region DA may be located on the opposite side of the gate electrode GE.

Each of the plurality of well areas WA may further include a first low-concentration impurity region LDD1 disposed between the channel region CH and the source region SA and a second low-concentration impurity region LDD2 disposed between the channel region CH and the drain region DA. The first low-concentration impurity region LDD1 may have a lower impurity concentration than the source region SA. The second low-concentration impurity region LDD2 may have a lower impurity concentration than the drain region DA. The distance between the source region SA and the drain region DA may be increased by the first low-concentration impurity region LDD1 and the second low-concentration impurity region LDD2. Therefore, the length of the channel region CH of each of the pixel transistors PTR is increased, and thus, punch-through and hot carrier phenomenon due to a short channel may be mitigated or prevented.

A first semiconductor insulating film SINS1 may be disposed on the semiconductor substrate SSUB. The first semiconductor insulating film SINS1 may be formed of, but is not limited to, a silicon carbon nitride (SiCN)- or a silicon oxide (SiOₓ)-based inorganic film.

A second semiconductor insulating film SINS2 may be disposed on the first semiconductor insulating film SINS1. The second semiconductor insulating film SINS2 may be formed of a silicon oxide (SiOₓ)-based inorganic film, but embodiments of the present disclosure are not limited thereto.

A plurality of contact terminals CTE may be disposed on the second semiconductor insulating film SINS2. Each of the plurality of contact terminals CTE may be connected to one of the gate electrode GE, the source region SA, and the drain region DA of each of the pixel transistors PTR through a hole (e.g., an opening) penetrating (or extending through) the first semiconductor insulating film SINS1 and the second semiconductor insulating film SINS2. The contact terminals CTE may be made of one of copper (Cu), aluminum (Al), tungsten (W), molybdenum (Mo), chromium (Cr), gold (Au), titanium (Ti), nickel (Ni), neodymium (Nd), or an alloy containing one or more of these.

A third semiconductor insulating film SINS3 may be disposed on the side surface of each of the contact terminals CTE. The upper surface of each of the contact terminals CTE may not be covered by the third semiconductor insulating film SINS3 but may be exposed. The third semiconductor insulating film SINS3 may be formed of a silicon oxide (SiOₓ)-based inorganic film, but embodiments of the present disclosure are not limited thereto.

In some embodiments, a glass substrate or a polymer resin substrate, such as polyimide, may be used instead of the semiconductor substrate SSUB. In such an embodiment, thin-film transistors may be disposed on a glass substrate or a polymer resin substrate. The glass substrate may be a rigid substrate that is not bent (or is not bendable), and the polymer resin substrate may be a flexible substrate that can be bent or curved.

The emission material backplane EBP includes first to eighth metal layers ML1 to ML8, reflective metal layers RL1 to RL4, a plurality of vias VA1 to VA10, and a step layer STPL. In addition, the emission material backplane EBP includes a plurality of interlayer dielectric films INS1 to INS10 disposed between the first to sixth metal layers ML1 to ML6.

The first to eighth metal layers ML1 to ML8 implement a circuit of a first sub-pixel SP1 by connecting a plurality of contact terminals CTE exposed from (or exposed by) the semiconductor backplane SBP.

The first interlayer insulating film INS1 may be disposed on the semiconductor backplane SBP. Each of the first vias VA1 may penetrate (or may extend through) the first interlayer insulating film INS1 and may be connected to the contact terminal CTE exposed from the semiconductor backplane SBP. Each of the first metal layers ML1 may be disposed on the first interlayer insulating film INS1 and may be connected to the first via VA1.

The second interlayer insulating film INS2 may be disposed on the first interlayer insulating film INS1 and the first metal layers ML1. Each of the second vias VA2 may penetrate through the second interlayer insulating film INS2 to be connected to the exposed first metal layer ML1. Each of the second metal layers ML2 may be disposed on the second interlayer insulating film INS2 and may be connected to the second via VA2.

The third interlayer insulating film INS3 may be disposed on the second interlayer insulating film INS2 and the second metal layers ML2. Each of the third vias VA3 may penetrate through the third interlayer insulating film INS3 to be connected to the exposed second metal layer ML2. Each of the third metal layers ML3 may be disposed on the third interlayer insulating film INS3 and may be connected to the third via VA3.

The fourth interlayer insulating film INS4 may be disposed on the third interlayer insulating film INS3 and the third metal layers ML3. Each of the fourth vias VA2 may penetrate through the fourth interlayer insulating film INS4 to be connected to the exposed third metal layer ML3. Each of the fourth metal layers ML4 may be disposed on the fourth interlayer insulating film INS4 and may be connected to the fourth via VA4.

The fifth interlayer insulating film INS5 may be disposed on the fourth interlayer insulating film INS4 and the fourth metal layers ML4. Each of the fifth vias VA5 may penetrate through the fifth interlayer insulating film INS5 to be connected to the exposed fourth metal layer ML4. Each of the fifth metal layers ML5 may be disposed on the fifth interlayer insulating film INS5 and may be connected to the fifth via VA5.

The sixth interlayer insulating film INS6 may be disposed on the fifth interlayer insulating film INS5 and the fifth metal layers ML5. Each of the sixth vias VA6 may penetrate through the sixth interlayer insulating film INS6 to be connected to the exposed fifth metal layer ML5. Each of the sixth metal layers ML6 may be disposed on the sixth interlayer insulating film INS6 and may be connected to the sixth via VA6.

The seventh interlayer insulating film INS7 may be disposed on the sixth interlayer insulating film INS6 and the sixth metal layers ML6. Each of the seventh vias VA7 may penetrate through the seventh interlayer insulating film INS7 to be connected to the exposed sixth metal layer ML6. Each of the seventh metal layers ML7 may be disposed on the seventh interlayer insulating film INS7 and may be connected to the seventh via VA7.

The eighth interlayer insulating film INS8 may be disposed on the seventh interlayer insulating film INS7 and the seventh metal layers ML7. Each of the eighth vias VA8 may penetrate through the eighth interlayer insulating film INS8 to be connected to the exposed seventh metal layer ML7. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may be made of substantially the same material. The first to eighth metal layers ML1 to ML8 and the first to eighth vias VA1 to VA8 may be made of one of copper (Cu), aluminum (Al), tungsten (W), molybdenum (Mo), chromium (Cr), gold (Au), titanium (Ti), nickel (Ni), neodymium (Nd), or an alloy containing one or more of these. The first to eighth vias VA1 to VA8 may be made of substantially the same material. The first to eighth interlayer insulating films INS1 to ILD8 may be formed of a silicon oxide (SiOₓ)-based inorganic film, but embodiments of the present disclosure are not limited thereto.

The thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first via VA1, the thickness of the second via VA2, the thickness of the third via VA3, the thickness of the fourth via VA4, the thickness of the fifth via VA5, and the thickness of the sixth via VA6, respectively. The thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially equal.

The thickness of the seventh metal layer ML7 and the thickness of the eighth metal layer ML8 may be greater than the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. The thickness of the seventh metal layer ML7 and the thickness of the eighth metal layer ML8 may be greater than the thickness of the seventh via VA7 and the thickness of the eighth via VA8. The thickness of the seventh via VA7 and the thickness of the eighth via VA8 may be greater than the thickness of the first via VA1, the thickness of the second via VA2, the thickness of the third via VA3, and the thickness of the fourth via VA4, the thickness of the fifth via VA5, and the thickness of the sixth via VA6. The thickness of the seventh metal layer ML7 may be substantially equal to the thickness of the eighth metal layer ML8.

The ninth interlayer insulating film INS9 may be disposed on the eighth interlayer insulating film INS8 and the eighth metal layers ML8. The ninth interlayer insulating film INS9 may be formed of a silicon oxide (SiOₓ)-based inorganic film, but embodiments of the present disclosure are not limited thereto.

Each of the ninth vias VA9 may penetrate through the ninth interlayer insulating film INS9 to be connected to the exposed eighth metal layer ML8. The ninth vias VA9 may be made of one of copper (Cu), aluminum (Al), tungsten (W), molybdenum (Mo), chromium (Cr), gold (Au), titanium (Ti), nickel (Ni), neodymium (Nd), or an alloy containing one or more of these.

The first reflective electrodes RL1 may be disposed on the ninth interlayer insulating film INS9 and may be connected to the ninth via VA9. The first reflective electrodes RL1 may be made of one of copper (Cu), aluminum (Al), tungsten (W), molybdenum (Mo), chromium (Cr), gold (Au), titanium (Ti), nickel (Ni), neodymium (Nd), or an alloy containing one or more of these.

The second reflective electrodes RL2 may be disposed on the first reflective electrodes RL1. The second reflective electrodes RL2 may be made of one of copper (Cu), aluminum (Al), tungsten (W), molybdenum (Mo), chromium (Cr), gold (Au), titanium (Ti), nickel (Ni), neodymium (Nd), or an alloy containing one or more of these. For example, the second reflective electrodes RL2 may be made of titanium nitride (TiN).

In the first sub-pixel SP1, a step layer STPL may be disposed on the second reflective electrode RL2. No step layer STPL may be disposed in each of the second sub-pixel SP2 and the third sub-pixel SP3. The thickness of the step layer STPL may be determined based on the wavelength of the light of a first color and the distance between a first emissive layer EML1 to a fourth reflective electrode RL4 so that the light of the first color emitted from the first emissive layer EML1 of the first sub-pixel SP1 is advantageously reflected. The step layer STPL may be formed of, but is not limited to, a silicon carbon nitride (SiCN) or a silicon oxide (SiOₓ)-based inorganic film.

In the first sub-pixel SP1, the third reflective electrode RL3 may be disposed on the second reflective electrode RL2 and the step layer STPL. In the second sub-pixel SP2 and the third sub-pixel SP3, the third reflective electrode RL3 may be disposed on the second reflective electrode RL2. The third reflective electrodes RL3 may be made of one of copper (Cu), aluminum (Al), tungsten (W), molybdenum (Mo), chromium (Cr), gold (Au), titanium (Ti), nickel (Ni), neodymium (Nd), or an alloy containing one or more of these.

In various embodiments, at least one of the first reflective electrode RL1, the second reflective electrode RL2, and the third reflective electrode RL3 may be omitted.

The fourth reflective electrodes RL4 may be disposed on the third reflective electrodes RL3. The fourth reflective electrodes RL4 may reflect light from the first to third intermediate layers EML1, EML2, and EML3. The fourth reflective electrodes RL4 may include a metal with high reflectivity to provide suitable light reflection. The fourth reflective electrodes RL4 may be made of, but is not limited to, aluminum (Al), a stack of aluminum and titanium (Ti/Al/Ti), a stack of aluminum and ITO (ITO/Al/ITO), silver (Ag), palladium (Pd), and an APC alloy, which is a copper (Cu) alloy, and a stack of an APC alloy and ITO (ITO/APC/ITO).

The tenth interlayer insulating film INS10 may be disposed on the ninth interlayer insulating film INS9 and the fourth reflective electrodes RL4. The tenth interlayer insulating film INS10 may be formed of a silicon oxide (SiOₓ)-based inorganic film, but embodiments of the present disclosure are not limited thereto.

Each of the tenth vias VA10 may penetrate through the tenth interlayer insulating film INS10 to be connected to the exposed ninth metal layer ML9. The tenth vias VA10 may be made of one of copper (Cu), aluminum (Al), tungsten (W), molybdenum (Mo), chromium (Cr), gold (Au), titanium (Ti), nickel (Ni), neodymium (Nd), or an alloy containing one or more of these. Due to the step layer STPL, the thickness of the tenth via VA10 in the first sub-pixel SP1 may be smaller than the thickness of the tenth via VA10 in each of the second sub-pixel SP2 and the third sub-pixel SP3.

The emission material layer EML may be disposed on the emission material backplane EBP. The emission material layer EML may include light-emitting elements LE, each including a first electrode AND, an intermediate layer IL, and a second electrode CAT, and a pixel-defining film PDL.

The first electrode AND of each of the light-emitting elements LE may be disposed on the tenth interlayer insulating film INS10 and may be connected to the tenth via VA10. The first electrode AND of each of the light-emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8, and the contact terminals CTE. The first electrode AND of each of the light-emitting elements LE may be made of one of copper (Cu), aluminum (Al), tungsten (W), molybdenum (Mo), chromium (Cr), gold (Au), titanium (Ti), nickel (Ni), neodymium (Nd), or an alloy containing one or more of these. For example, the first electrode AND of each of the light-emitting elements LE may be made of titanium nitride (TiN).

The pixel-defining film PDL may be partially disposed on the first electrode AND of each of the light-emitting elements LE. The pixel-defining film PDL may cover an edge of the first electrode AND of each of the light-emitting elements LE. The pixel-defining film PDL partitions the first emission areas EA1, the second emission areas EA2, and the third emission areas EA3.

A first emission area EA1 may be defined as an area in the first sub-pixel SP1 at where the first electrode AND, the intermediate layer IL, and the second electrode CAT are sequentially stacked on one another to emit light. A second emission area EA2 may be defined as an area in the second sub-pixel SP2 at where the first electrode AND, the intermediate layer IL, and the second electrode CAT are sequentially stacked on one another to emit light. A third emission area EA3 may be defined as an area in the third sub-pixel SP3 at where the first electrode AND, the intermediate layer IL, and the second electrode CAT are sequentially stacked on one another to emit light.

The pixel-defining film PDL may include first to third pixel-defining films PDL1, PDL2, and PDL3. The first pixel-defining film PDL1 may be disposed on the edge of the first electrode AND of each of the light-emitting elements LE, the second pixel-defining film PDL2 may be disposed on the first pixel-defining film PDL1, and the third pixel-defining film PDL3 may be disposed on the second pixel-defining film PDL2. The first pixel-defining film PDL1, the second pixel-defining film PDL2, and the third pixel-defining film PDL3 may be formed of a silicon oxide (SiOₓ)-based inorganic film, but embodiments of the present disclosure are not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2, and IL3 that emit different light (e.g., that emit different color light). For example, the intermediate layer IL may include the first intermediate layer IL1 that emits light of the first color, the second intermediate layer IL2 that emits light of the third color, and the third intermediate layer IL3 that emits light of the second color. The first intermediate layer IL1, the second intermediate layer IL2, and the third intermediate layer IL3 may be sequentially stacked on one another.

The first intermediate layer IL1 may have a structure in which a first hole transport layer, a first organic emissive layer that emits light of the first color, and a first electron transport layer are sequentially stacked on one another. The second intermediate layer IL2 may have a structure in which a second hole transport layer, a second organic emissive layer that emits light of the third color, and a second electron transport layer are sequentially stacked on one another. The third intermediate layer IL3 may have a structure in which a third hole transport layer, a third organic emissive layer that emits light of the second color, and a third electron transport layer are sequentially stacked on one another.

The intermediate layer IL may cover the first electrode AND at (or in) an opening in the pixel-defining film PDL, may cover the pixel-defining film PDL between adjacent sub-pixels SP1, SP2 and SP3, and may be partially disconnected.

According to an embodiment, leakage current between adjacent sub-pixel SP1, SP2, and SP3 and color crosstalk may be mitigated or prevented by disconnecting the intermediate layer IL between the adjacent sub-pixel SP1, SP2, and SP3. Color crosstalk refers to, for example, a phenomenon in which a red sub-pixel adjacent to a blue sub-pixel is unintentionally turned when the blue sub-pixel emits blue light. Because color crosstalk occurs due to leakage current, it may occur if a blue sub-pixel and a red sub-pixel, which have a large difference in voltage for driving the sub-pixels, are adjacent to each other. For example, while the driving current is supplied to the light-emitting element LE of a blue sub-pixel to turn on the blue sub-pixel, some of the driving current may be transmitted to a red sub-pixel through at least some conductive layers of the intermediate IL, which is leakage current. If leakage current is generated, the red sub-pixel may be unintentionally turned on when the blue sub-pixel is turned on.

The number of intermediate layers IL1, IL2, and IL3 emitting different lights is not limited to that shown in FIG. 5. For example, in another embodiment, the intermediate layer IL may include two intermediate layers. In such an embodiment, one of the two intermediate layers is substantially identical to the first intermediate layer IL1, and the other one may include a second hole transport layer, a second organic emissive layer, a third organic emissive layer, and a second electron transport layer. In such an embodiment, a charge generation layer may be disposed between the two intermediate layers to supply electrons to one intermediate layer and to supply charges to the other intermediate layer.

In addition, although the first to third intermediate layers IL1, IL2, and IL3 are all disposed in the first emission area EA1, the second emission area EA2, and the third emission area EA3 in the embodiment shown in FIG. 5, embodiments of the present disclosure are not limited thereto. For example, the first intermediate layer IL1 may be disposed in the first emission area EA1 but not in the second emission area EA2 and the third emission area EA3. In addition, the second intermediate layer IL2 may be disposed in the second emission area EA2 but not in the first emission area EA1 and the third emission area EA3. In addition, the third intermediate layer IL3 may be disposed in the third emission area EA3 but not in the first emission area EA1 and the second emission area EA2. In various embodiments, the first to third color filters CF1, CF2, and CF3 of the optical layer OPL may be omitted.

The second electrode CAT may be disposed on the third intermediate layer IL3. The second electrode CAT may be disposed on the third intermediate layer IL3 in each of a plurality of trenches TRC. The second electrode CAT may be formed of a transparent conductive material (TCP), such as ITO and IZO, that can transmit light or a semi-transmissive conductive material, such as magnesium (Mg), silver (Ag), and an alloy of magnesium (Mg) and silver (Ag). When the second electrode CAT is formed of a semi-transmissive conductive material, the light extraction efficiency can be increased by using microcavities in each of the first to third sub-pixels SP1, SP2, and SP3.

The encapsulation layer TFE may be disposed on the emission material layer EML. The encapsulation layer TFE may include one or more inorganic films TFE1 and TFE2 to reduce or prevent permeation of oxygen or moisture into the emission material layer EML. In addition, the encapsulation layer ENC may include at least one organic film to protect the emission material layer EML from particles, such as dust. For example, the encapsulation layer ENC may include a first inorganic encapsulation film TFE1, an organic encapsulation film TFE2, and a second inorganic encapsulation film TFE3.

The first inorganic encapsulation film TFE1 may be disposed on the second electrode CAT, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made of multiple layers in which one or more inorganic layers of a silicon nitride (SiNₓ) layer, a silicon oxynitride (SiON) layer, a silicon oxide (SiOₓ) layer, a titanium oxide (TiOₓ) layer, and an aluminum oxide layer (AlOₓ) are alternately stacked on one another. The organic encapsulation film TFE2 may be a monomer. In another embodiment, the organic encapsulation film TFE2 may be an organic film, such as an acryl resin, an epoxy resin, a phenolic resin, a polyamide resin, a polyimide resin, etc.

An adhesive layer ADL may adhere the encapsulation layer TFE to the optical layer OPL. The adhesive layer ADL may be a double-sided adhesive member. In addition, the adhesive layer ADL may be a transparent adhesive member, such as a transparent adhesive and a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the adhesive layer ADL.

The first color filter CF1 may be in line with (e.g., may be aligned with) the first emission area EA1 of the first sub-pixel SP1. The first color filter CF1 may transmit light of the first color (e.g., light in the blue wavelength range). The blue wavelength range may be in a range of approximately 370 nm to approximately 460 nm. Therefore, the first color filter CF1 may transmit light of the first color from among the light emitted from the first emission area EA1.

The second color filter CF2 may be in line with the second emission area EA2 of the second sub-pixel SP2. The second color filter CF2 may transmit light of the second color (e.g., light in the green wavelength range). The green wavelength range may be in a range of approximately 480 nm to approximately 560 nm. Therefore, the second color filter CF2 may transmit light of the second color from among the light emitted from the second emission area EA2.

The third color filter CF3 may be in line with the third emission area EA3 of the third sub-pixel SP3. The third color filter CF3 may transmit light of the third color (e.g., light in the red wavelength range). The blue wavelength range may be in a range of approximately 600 nm to approximately 750 nm. Therefore, the third color filter CF3 may transmit light of the third color from among the light emitted from the third emission area EA3.

The lenses LNS may be disposed on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is upwardly convex.

The filling layer FIL may be disposed on a plurality of lenses LNS. The filling layer FIL may have a refractive index (e.g., a predetermined refractive index) so that light travels in the third direction DR3 at the interface between the plurality of lenses LNS and the filling layer FIL. In addition, the filling layer FIL may be a planarization layer. The filling layer FIL may be an organic film, such as an acryl resin, an epoxy resin, a phenolic resin, a polyamide resin, and a polyimide resin.

The cover layer CVL may be disposed on the filling layer FIL. The cover layer CVL may be a glass substrate or a polymer resin, such as polyimide. When the cover layer CVL is a glass substrate, it may be attached to the filling layer FIL. In such an embodiment, the filling layer FIL may adhere the cover layer CVL. When the cover layer CVL is a glass substrate, it may act as an encapsulation substrate. When the cover layer CVL is a polymer resin, such as a polyimide, it may be applied directly on the filling layer FIL.

A polarizer may be disposed on a surface of the cover layer CVL. The polarizer may be a structure for preventing deterioration of visibility due to reflection of external light. The polarizer may include a linear polarizer and a retardation film. For example, the retardation film may be a λ/4 plate (quarter-wave plate), but embodiments of the present disclosure are not limited thereto. If visibility is sufficiently improved by the first to third color filters CF1, CF2, and CF3 regardless of reflection of external light, the polarizer may be omitted.

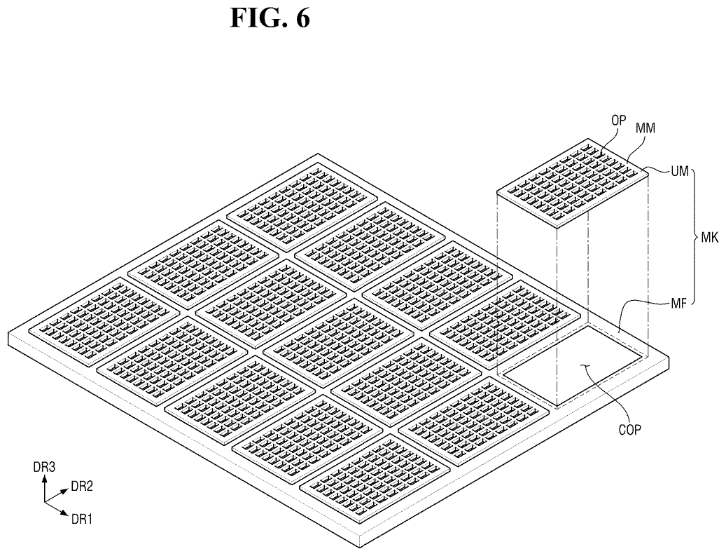

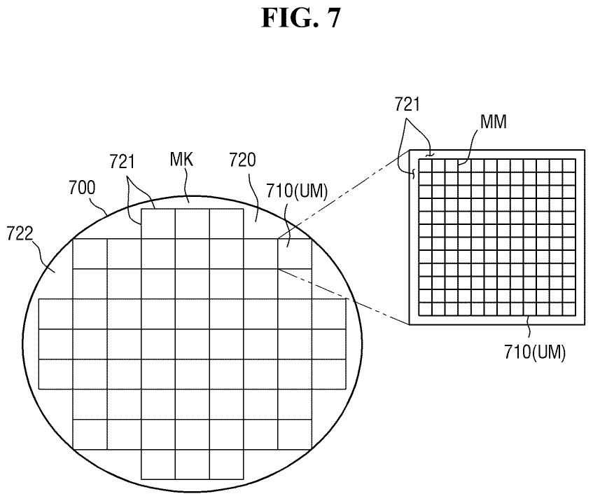

FIG. 6 is a perspective view of a mask according to an embodiment. FIG. 7 is a schematic plan view of a mask according to an embodiment of the present disclosure. In the perspective view of FIG. 6, a unit mask UM is separated from a plurality of unit masks. The mask according to the embodiment shown in FIGS. 6 and 7 may be used in a process of depositing at least a portion of the intermediate layer IL of the display panel 410 described above with reference to FIG. 5. For example, the intermediate layer IL may emit different colors in the sub-pixels SP1, SP2, and SP3.

Referring to FIGS. 6 and 7, a mask MK according to an embodiment may be a shadow mask in which a mask membrane MM is disposed on a silicon substrate 700. The mask MK may be referred to as a silicon mask.

According to an embodiment, the mask MK may include a silicon substrate 700, and a mask membrane MM may be disposed on the silicon substrate 700.

The silicon substrate 700 may be a silicon on insulator (SOI) substrate. The SOI substrate may be a silicon substrate including an upper silicon substrate, a lower silicon substrate, and an insulating layer disposed between the upper silicon substrate and the lower silicon substrate. The SOI substrate differs from a typical silicon wafer composed of only a silicon single crystal in that an insulating layer is disposed between the silicon single crystal layers (e.g., the upper silicon substrate and the lower silicon substrate). Such SOI substrates have strong resistance to process stress because they provide a defect-free silicon layer blocked by an insulating layer. One embodiment of the present disclosure processes the upper silicon substrate of such SOI substrate to form a mask membrane MM, thereby providing a deposition mask that is thin yet has a strong stress resistance. In the following description, reference numeral 700 refers to an SOI substrate.

In the present document, the upper silicon substrate may be referred to as a “first silicon substrate” and the lower silicon substrate may be referred to as a “second silicon substrate.” Alternatively, the upper silicon substrate may be named “second silicon substrate” and the lower silicon substrate may be named “first silicon substrate”.

The mask membrane MM may be disposed in cell areas 710 arranged in a matrix, and each cell area 710 may be surrounded (e.g., surrounded in a plan view) by a mask rib region 721.

The mask membrane MM may be a part of the unit mask UM disposed in each of a plurality of cell areas 710. The mask membrane MM may be formed by patterning the upper silicon substrate.

The SOI substrate 700 may include a plurality of cell areas 710 and a mask frame area 720 other than the plurality of cell areas 710. The mask frame area 720 may include a mask rib region 721 surrounding each cell area 710, and an outer frame region 722 disposed at the outermost position of (e.g., forming an outer periphery of) the SOI substrate 700. A mask frame MF is disposed in the mask frame area 720, and the mask frame MF may include a mask rib surrounding the cell areas 710.

The mask rib region 721 may partition a plurality of cell areas 710. For example, the plurality of cell areas 710 may be arranged in a matrix, and the mask rib region 721 may surround the cell areas 710.

A cell opening COP and a unit mask UM that at least partially masks the cell opening COP may be located in each of the plurality of cell areas 710 of the SOI substrate 700.

The plurality of cell openings COP may penetrate (or may extend through) the mask frame MF along the thickness direction of the mask MK (e.g., the third direction DR3). The plurality of cell openings COP may be created by etching the lower silicon substrate of the SOI substrate 700 from the rear side.

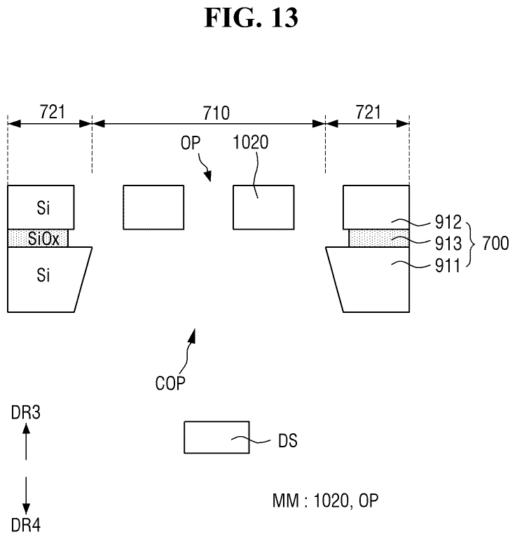

Each unit mask UM may include a mask membrane MM, and the mask membrane MM may have mask openings OP. The mask shadows 1020 (see, e.g., FIG. 13) may be arranged in a matrix in each unit mask UM, and the mask openings OP (see, e.g., FIG. 13) may be located between the mask shadows 1020. For example, the mask shadows 1020 may be arranged to surround (e.g., to extend around a periphery of) the mask openings OP.

The mask shadows 1020 can act as a blocking unit that masks a substrate subject to deposition (e.g., the display panel 410 or backplane substrate) when the deposition material evaporates from a deposition source DS (see, e.g., FIG. 13) inside the deposition machine. Accordingly, the deposition material generated from the deposition source DS may be deposited on the surface of the substrate subjected to deposition (e.g., the display panel 410 or backplane substrate) through the mask openings OP in the mask membrane MM.

The mask openings OP in the mask membrane MM may be referred to as holes or mask holes. The mask openings OP may penetrate the unit masks UM along the thickness direction of the mask MK (e.g., the third direction DR3).

One unit mask UM may be used in a process of depositing one display panel 410. As used herein, the term “unit mask UM” may be interchangeably used with terms such as “mask unit UM” and “unit mask UM.”

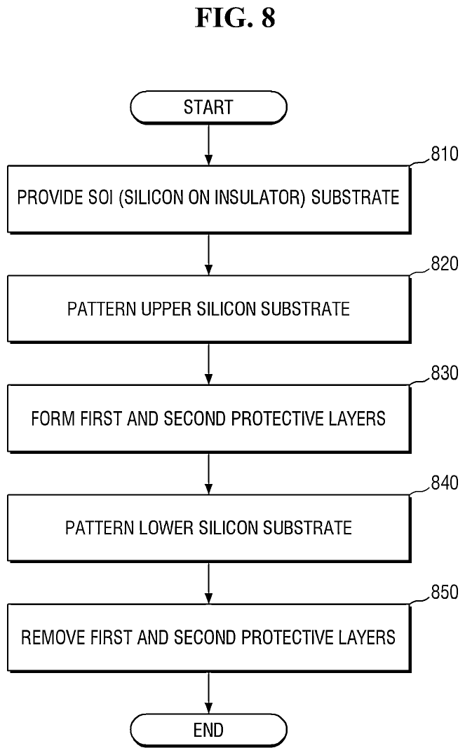

FIG. 8 is a flowchart describing steps of a method of fabricating a mask according to an embodiment of the present disclosure.

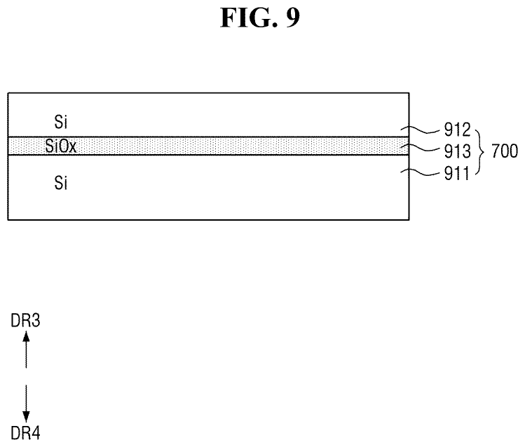

FIGS. 9 to 13 are cross-sectional views illustrating steps of the method of fabricating a mask described in FIG. 8.

Hereinafter, with reference to FIGS. 8 to 14, a method of fabricating a mask according to an embodiment will be described. It should be noted that only some of fabrication processes of the mask will be described. Other processes for forming the elements described herein may be additionally performed before or after the fabrication processes described below. In addition, fabrication processes of masks known in the art may be additionally performed before or after the fabrication processes described below.

Referring to FIGS. 8 and 9, in step 810, a SOI substrate 700 may be prepared. The SOI substrate 700 may be a silicon substrate including an upper silicon substrate 912, a lower silicon substrate 911, and an insulating layer 913 disposed between the upper silicon substrate 912 and the lower silicon substrate 911. The insulating layer 913 may include silicon oxide (SiOₓ).

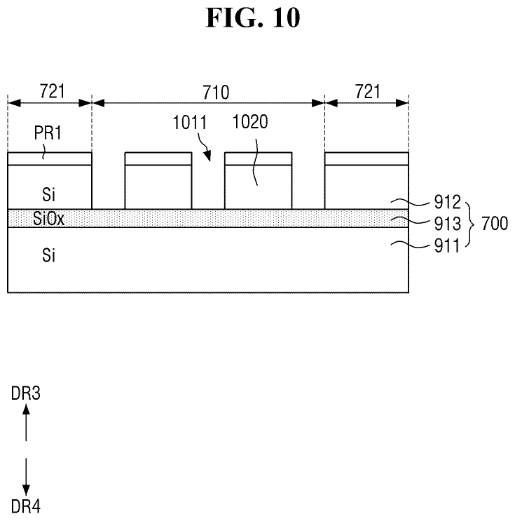

Referring to FIGS. 8 and 10, in step 820, the upper silicon substrate 912 may be patterned. The step of patterning the upper silicon substrate 912 includes forming a first photoresist pattern PR1 on the upper silicon substrate 912, forming a plurality of openings 1011 in the upper silicon substrate 912 by using (or according to) the first photoresist pattern PR1, and removing the first photoresist pattern PR1.

In step 820, the upper silicon substrate 912 of the SOI substrate 700 is partially patterned in each cell area 710 to form a plurality of openings 1011. After the process according to step 820, a portion of the upper silicon substrate 912 remaining in each cell area 710 may act as a mask membrane MM. For example, the portion of the upper silicon substrate 912 remaining in each cell area 710 may become mask shadows 1020 of the mask membrane MM. After the process according to step 820, the plurality of openings 1011 formed in each cell area 710 may act as mask openings OP in the mask membrane MM.

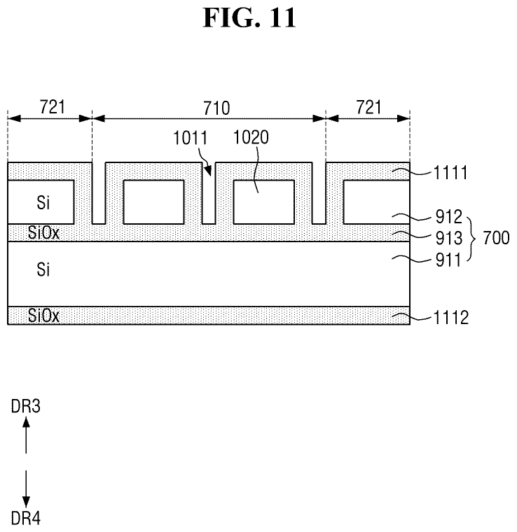

Referring to FIGS. 8 and 11, in step 830, a first protective layer 1111 and a second protective layer 1112 are formed. The first protective layer 1111 may be an oxide film formed on the surface of the upper silicon substrate 912. The second protective layer 1112 may be an oxide film formed on the surface of the lower silicon substrate 911. For example, the step of forming the first protective layer 1111 and the second protective layer 1112 includes performing a thermal oxidation process on the upper silicon substrate 912 and the lower silicon substrate 911.

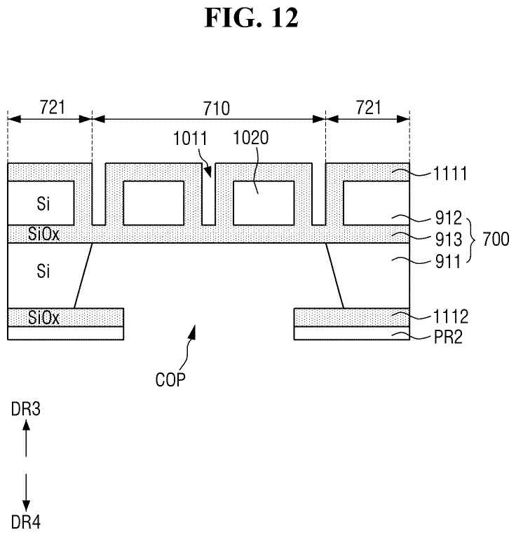

Referring to FIGS. 8 and 12, in step 840, the lower silicon substrate 911 is patterned. In step 840, the lower silicon substrate 911 is patterned in each cell area 710 to form a cell opening COP. The step of forming the cell opening COP may include KOH wet etching by adjusting the etch ratio in respect to silicon oxide (SiOₓ) included in the second protective layer 1112 and silicon (Si) included in the lower silicon substrate 911.

Referring to FIGS. 8 and 13, in step 850, the first protective layer 1111 and the second protective layer 1112 are removed. The step of removing the first protective layer 1111 and the second protective layer 1112 may include a strip process using a wet chemical, for example, HF or buffered oxide etchant (BOE). After the first protective layer 1111 and the second protective layer 1112 are removed, the SOI substrate 700 may become a silicone mask in which a portion of the upper silicon substrate 912 patterned in each cell area 710 acts as the mask membrane MM. For example, the mask membrane MM may include mask shadows 1020 formed of the patterned upper silicon substrate 912 and a mask opening OP disposed between the mask shadows 1020. The mask membrane MM may be disposed to face a deposition source DS through the cell opening COP formed by (or formed in) the lower silicon substrate 911 patterned in each cell area 710.

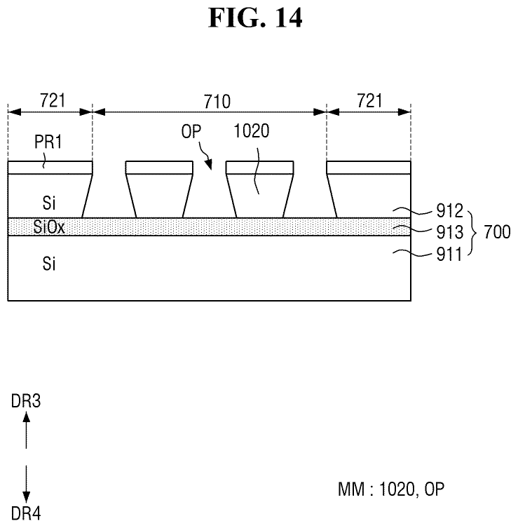

FIG. 14 is a cross-sectional view illustrating a step of a method of patterning an upper silicone substrate 912 according to an embodiment of the present disclosure.

According to an embodiment, the mask membrane MM formed by patterning the upper silicon substrate 912 may have an inverse taper shape. For example, the cross-section of the mask membrane MM may have an inverse taper shape in which the thickness increases from the bottom surface (e.g., the surface facing a fourth direction DR4) toward the upper direction DR3.

For the mask membrane MM to have the inverse taper shape cross-section, the process according to step 820 described with reference to FIG. 8 may form a plurality of openings 1011 but may etch the upper silicon substrate 912 so that each opening includes an undercut area.

The mask (e.g., MK in FIG. 7) according to an embodiment can reduce the area of the shadow region because the cross-section of the mask membrane MM (e.g., the cross-section of the mask shadow 1020) has an inverse taper shape. For example, the taper angle of the cross-section of the mask shadow 1020 may be smaller than or equal to the deposition incident angle, which is the minimum angle from the deposition source DS to the mask opening OP, and thus, the area of the shadow region can be reduced.

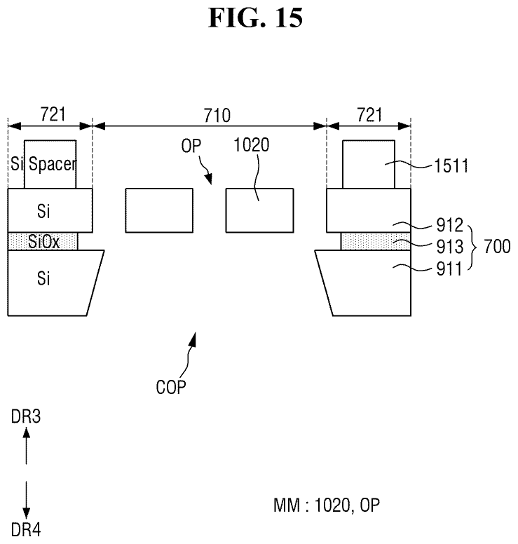

FIG. 15 is a schematic cross-sectional view of a deposition mask including spacers 1511 according to an embodiment.

Referring to FIG. 15, a mask according to an embodiment may include a spacer 1511 having a height and facing the substrate subjected to deposition. The substrate subjected to deposition may be the display panel 410 described with reference to FIGS. 4 and 5.

As described above, the SOI substrate 700 includes a plurality of cell areas 710 and a mask rib region 721 surrounding the plurality of cell areas 710. The SOI substrate 700 may include a spacer 1511 formed by etching the upper silicon substrate 912 in the mask rib region 721.

The spacer 1511 may be formed by etching the upper silicon substrate 912 in the mask rib region 721. The spacer 1511 generates tensile force through physical contact with the substrate subjected to deposition (e.g., the display panel 410) and prevents the mask membrane MM from sagging.

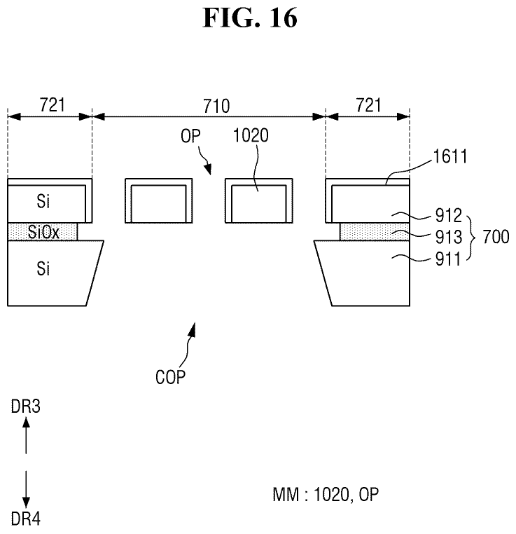

FIG. 16 is a schematic cross-sectional view of a deposition mask including a dummy inorganic film 1611 according to an embodiment.

According to an embodiment, the mask MK may have an additional inorganic film 1611 deposited on the surface of the mask membrane MM to prevent the mask membrane MM from sagging. For example, the inorganic film 1611 deposited on the surface of the mask membrane MM may be referred to as a “dummy inorganic film 1611,” but the present disclosure is not limited thereto. For example, the dummy inorganic film 1611 may be referred to by various terms, such as “additional inorganic film”, “protective inorganic film”, etc.

The process of depositing the dummy inorganic film 1611 may be performed after the process of removing the first protective layer 1111 and the second protective layer 1112, for example, after step 850 of FIG. 8.

The dummy inorganic film 1611 may include silicon nitride (SiNₓ), but the material of the dummy inorganic film 1611 is not limited thereto.

According to an embodiment, during the deposition process of the dummy inorganic film 1611, the cross-section of the mask membrane MM may have an inverse taper shape by adjusting the deposition thickness of the dummy inorganic film 1611. For example, a step of adjusting the deposition thickness on the side of the mask shadow 1020 of the mask membrane MM so that the cross-section of the mask opening OP in the mask membrane MM has a regular taper shape may be included.

According to embodiments of the present disclosure, a mask membrane MM may be formed by using a portion of the silicon layer included in the SOI (Silicon on Insulator) substrate so that the mask membrane MM is thin yet has strong resistance to stress.

In concluding the detailed description, those skilled in the art will appreciate that many variations and modifications can be made to the embodiments described herein without substantially departing from the present disclosure. Therefore, the disclosed embodiments of the present disclosure are used in a generic and descriptive sense and not for purposes of limitation.

What is claimed is:

1. A method of fabricating a deposition mask, the method comprising:
preparing a silicon on insulator (SOI) substrate comprising an upper silicon substrate, a lower silicon substrate, and an insulating layer between the upper silicon substrate and the lower silicon substrate;
forming a mask membrane having a plurality of openings by patterning the upper silicon substrate;
forming a first protective layer on the upper silicon substrate and a second protective layer on the lower silicon substrate;
forming a cell opening by patterning the lower silicon substrate; and
removing the first protective layer and the second protective layer.

2. The method of claim 1, wherein the insulating layer comprises silicon oxide.

3. The method of claim 1, wherein the patterning of the upper silicon substrate comprises:
forming a first photoresist pattern on the upper silicon substrate;
forming the plurality of openings by using the first photoresist pattern; and
removing the first photoresist pattern.

4. The method of claim 3, wherein the forming of the first protective layer and the second protective layer comprises performing thermal oxidation process with respect to the upper silicon substrate and the lower silicon substrate, respectively.

5. The method of claim 3, wherein the forming of the cell opening comprises KOH wet etching process by adjusting an etch ratio in respect to silicon oxide in the second protective layer and silicon in the lower silicon substrate.

6. The method of claim 5, wherein the removing of the first protective layer and the second protective layer comprises a strip process by using HF or buffered oxide etchant.

7. The method of claim 1, wherein the SOI substrate has a plurality of cell areas and a mask rib region extending around the plurality of cell areas, and
wherein the method further comprises forming a spacer by etching the upper silicon substrate in the mask rib region.

8. The method of claim 7, wherein the spacer has a height facing a substrate to be subjected to deposition.

9. The method of claim 1, further comprising depositing a dummy inorganic film covering the mask membrane after the removing of the first protective layer and the second protective layer.

10. The method of claim 9, wherein the dummy inorganic film comprises silicon nitride.

11. The method of claim 10, wherein the depositing of the dummy inorganic film comprises adjusting a deposition thickness on a side of a mask shadow of the mask membrane so that a cross-section of a mask opening in the mask membrane has a taper shape.

12. The method of claim 1, wherein the forming of the mask membrane comprises forming a cross-section of the mask membrane into an inverse taper shape.

13. The method of claim 12, wherein the inverse taper shape of the cross-section of the mask membrane has a shape in which its thickness increases from a bottom surface in an upward direction.

14. A deposition mask comprising:
a silicon on insulator (SOI) substrate comprising an upper silicon substrate, a lower silicon substrate, and an insulating layer between the upper silicon substrate and the lower silicon substrate;
a mask membrane formed by etching the upper silicon substrate in each cell area of the SOI substrate; and
a cell opening exposing the mask membrane from a rear direction in each of the cell areas.

15. The deposition mask of claim 14, wherein the insulating layer comprises silicon oxide.

16. The deposition mask of claim 14, wherein the SOI substrate has a plurality of cell areas and a mask rib region extending around the plurality of cell areas, and
wherein the deposition mask further comprises a spacer formed by etching the upper silicon substrate in the mask rib region.

17. The deposition mask of claim 16, wherein the spacer has a height facing a substrate to be subjected to deposition.

18. The deposition mask of claim 14, further comprising a dummy inorganic film covering the mask membrane.

19. The deposition mask of claim 18, wherein the dummy inorganic film comprises silicon nitride.

20. The deposition mask of claim 14, wherein a cross-section of the mask membrane has an inverse taper shape, and
wherein the inverse taper shape is a shape having a thickness that increases from a bottom surface in an upward direction.
